(19) United States
(12) Patent Application Publication
(10) Pub. No.: US 2026/0051794 A1
(43) Pub. Date: Feb. 19, 2026

(54) SERVO MOTOR AND SEMICONDUCTOR EQUIPMENT

(71) Applicant: DELTA ELECTRONICS, INC., Taoyuan City (TW)

(72) Inventor: Fu-Mei HSU, Taoyuan City (TW)

(21) Appl. No.: 19/002,685

(22) Filed: Dec. 27, 2024

(30) Foreign Application Priority Data
Aug. 19, 2024 (CN) 2024111364645

(51) Int. Cl. H02K 11/22; B25J 15/06; H01L 21/683; H02K 1/278; H02K 5/10; H02K 7/00; H02K 21/14

(52) U.S. Cl. CPC H02K 11/22; B25J 15/0616; H01L 21/6838; H02K 1/278; H02K 5/10; H02K 7/003; H02K 21/14; H02K 2205/09

(57) ABSTRACT

A servo motor includes a motor and an encoder. The motor includes a housing, a stator and a rotating shaft. The housing includes a first vent hole. The stator is positioned in the housing. The rotating shaft is installed in the housing and rotated by the electromagnetic action of the stator. The rotating shaft is partially hollow, and at least one second vent hole is defined on the rotating shaft for gas to circulate between the first and second vent holes. The encoder is located in the housing to detect the rotation information of the motor and encode the rotation information into a signal. Additionally, a semiconductor device including a servo motor and a loading module is disclosed.

### BACKGROUND OF THE DISCLOSURE

### Technical Field

The technical field relates to a motor, and more particularly relates to a servo motor used in a semiconductor processing equipment.

### Description of Related Art

Currently, in the servo motors used for semiconductor processes, the rotating shaft is equipped with a through hole that extends from the front to the back of the output shaft, allowing gas to pass through the rotating shaft from one side of the motor to the other to achieve a vacuum suction effect. Additionally, an encoder is installed inside the motor to control the motor's rotational speed.

Furthermore, the coating process environment in the semiconductor industry is filled with acidic and alkaline solutions and gases, but the encoder inside the motor must be kept free from contamination to ensure accurate optical signals. In this regard, it is necessary to install shaft seals between the front and rear output shafts and the housing to isolate dirt and protect the encoder. Furthermore, the motor speed has been increasing due to market demand; however, the increase in speed means that the wear, aging, or deterioration of the shaft seals accelerates, leading to a decrease in the ability to isolate dirt.

In view of the above drawbacks, the inventor proposes this disclosure based on his expert knowledge and elaborate researches in order to solve the problems of related art.

### SUMMARY OF THE DISCLOSURE

This disclosure provides a servo motor that maintains the accuracy and lifespan of the encoder and may be connected to a vacuum device to generate negative pressure suction.

This disclosure is a servo motor including a motor and an encoder. The motor includes a housing, a stator and a rotating shaft. The housing includes a first vent hole. The stator is positioned in the housing. The rotating shaft is installed in the housing and is configured to rotate by the electromagnetic action of the stator. The rotating shaft is partially hollow, and at least one second vent hole is defined on the rotating shaft for gas to circulate between the first vent hole and the second vent hole. The encoder is located in the housing and is configured to detect a rotation information of the motor and encode the rotation information into a signal.

This disclosure is a semiconductor equipment for driving a wafer. The semiconductor equipment includes a servo motor and a loading module. The loading module is positioned on the rotating shaft of the servo motor, driven by the rotating shaft of the servo motor, and rotates on one side of the servo motor. The wafer is sucked by negative pressure and rotates with the loading module.

In one embodiment of this disclosure, the housing comprises a back cover sealing the encoder, and the back cover is located on a rear side of the rotating shaft and free from covering the first vent hole.

In one embodiment of this disclosure, the rotating shaft comprises a front shaft section, a middle shaft section, and a rear shaft section, the front shaft section comprises a hollow passage, the front shaft section is partially hollow and protrudes from the housing, the middle shaft section is located corresponding to the stator, the second vent hole is defined on the middle shaft section, an end of the second vent hole communicates with the hollow passage, the rear shaft section extends from the middle shaft section, and the encoder is combined on an end of the rear shaft section.

In one embodiment of this disclosure, the hollow passage is located at a center of the front shaft section and extends from the front shaft section to the middle shaft section.

In one embodiment of this disclosure, a groove is defined on the middle shaft section, and the second vent hole is located corresponding to the groove.

In one embodiment of this disclosure, the number of the second vent hole is multiple, and a plurality of second vent holes are spacedly defined on the middle shaft section and communicating to the hollow passage.

In one embodiment of this disclosure, second vent holes are defined on the middle shaft section and located on two sides of the hollow passage.

In one embodiment of this disclosure, the rotating shaft comprises a rotor silicon sheet and a plurality of magnets, the rotor silicon sheet surrounds an inner side of the stator, and the magnets are attached to outside of the rotor silicon sheet.

In one embodiment of this disclosure, a groove is defined on a middle part of the rotating shaft, the groove is located on the rotor silicon sheet, and the second vent hole extends to a position of the rotor silicon sheet and is corresponding to the groove.

In comparison with the related art, the servo motor in this disclosure is designed with a first vent hole defined on the housing, and the rotating shaft is partially hollow and has a second vent hole, which allows gas to circulate through the first and second vent holes. Additionally, through the aforementioned gas flow channel design, the encoder is mounted on the rotating shaft inside the housing, and the housing is sealed without the need for additional sealing structures attached to the encoder, thereby simplifying the assembly of the servo motor and reducing costs. Furthermore, the servo motor utilizes a reflective encoder, which has advantages such as easy assembly and a small size. Moreover, since the encoder is located in a closed space, it has high sealing performance and greater reliability. Additionally, due to the small size of the reflective encoder and its limited contact area with the motor body, heat from the motor may not be transferred to the encoder and may be dissipated directly to the outside, thus improving the motor's heat dissipation efficiency.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 and FIG. 2 depict perspective schematic views of the servo motor from two sides according to this disclosure.

FIG. 3 and FIG. 4 depict cross-sectional views of the servo motor from two sides according to this disclosure.

FIG. 5 depicts a perspective exploded view of the rotating shaft according to this disclosure.

FIG. 6 depicts a cross-sectional view of the rotating shaft according to this disclosure.

FIG. 7 depicts another embodiment of the servo motor with a groove defined on the rotating shaft according to this disclosure.

FIG. 8 is another embodiment of the encoder of the servo motor according to this disclosure.

FIG. 9 is an application schematic view of the servo motor according to this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

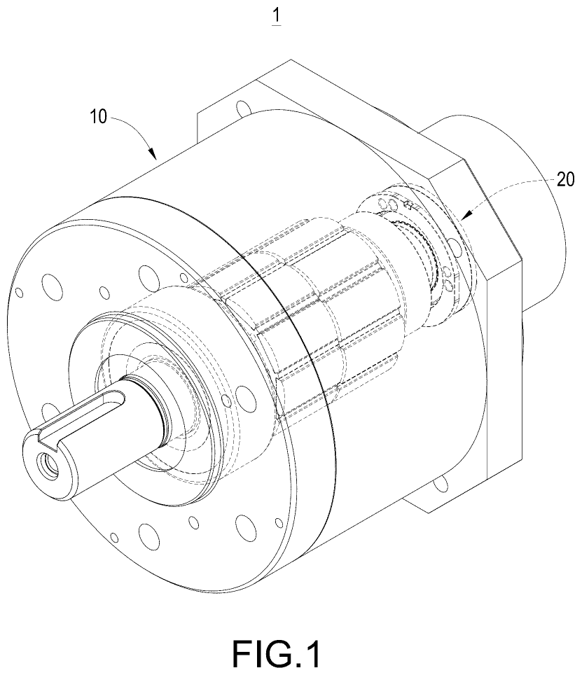

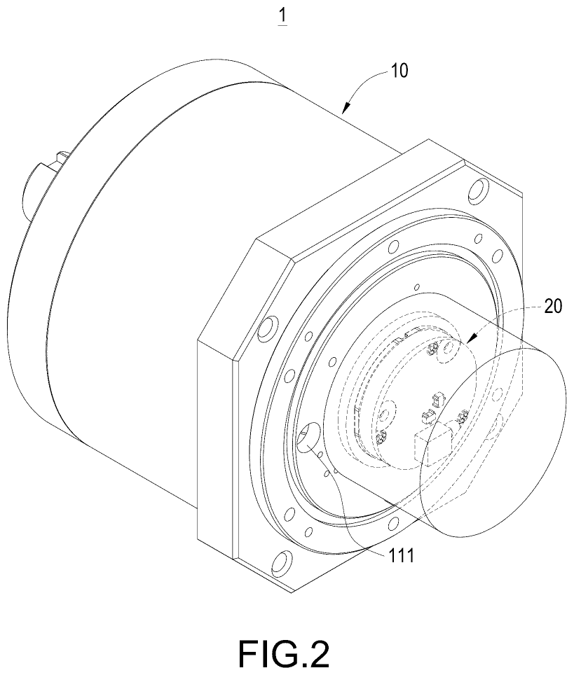

Please refer to FIG. 1 and FIG. 2, which depict perspective schematic views of the servo motor from two sides according to this disclosure. The servo motor 1 includes a motor 10 and an encoder 20. The encoder 20 is disposed inside the motor 10 to sense the rotation of the motor 10 and transmit signals. A more detailed description of the structure of the servo motor 1 is described as follows.

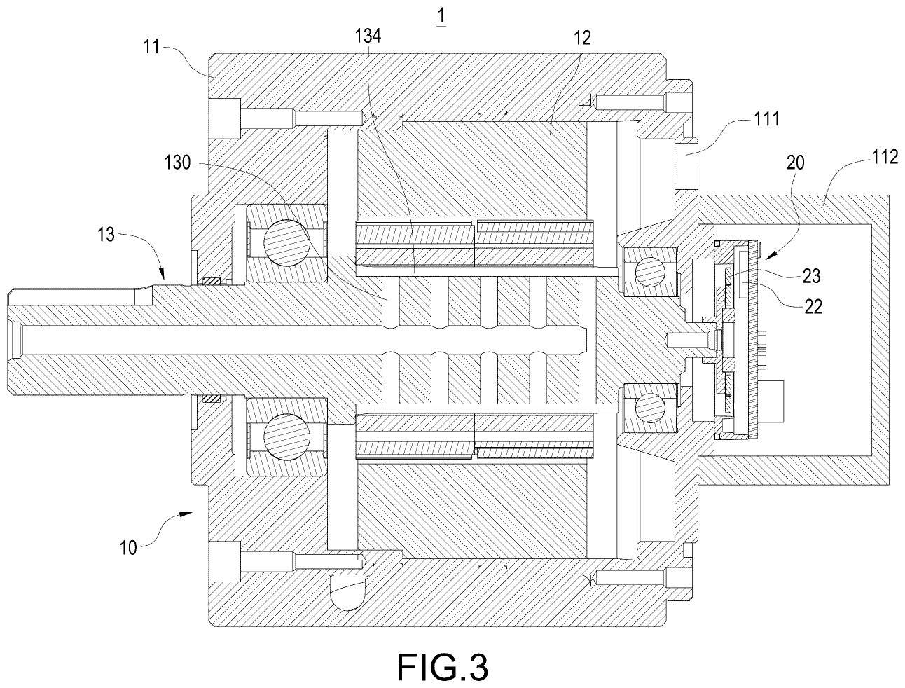

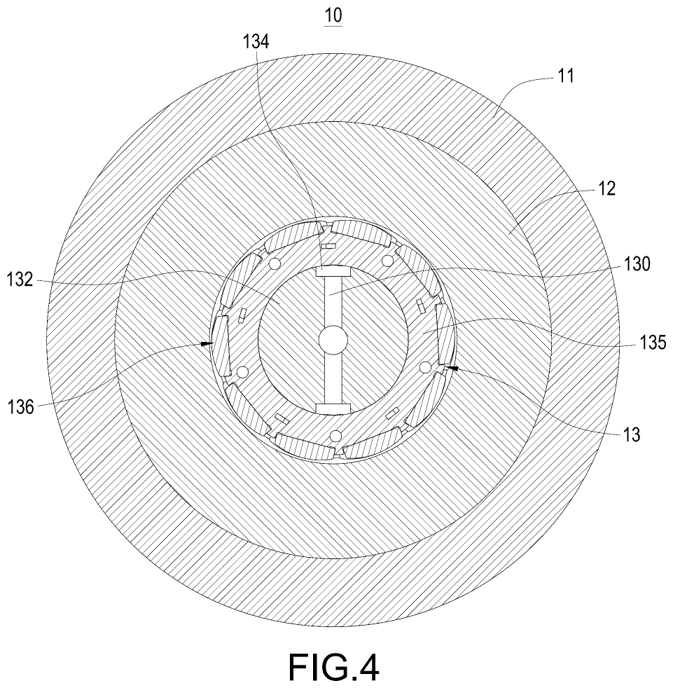

Please further refer to FIG. 3 and FIG. 4, which depict cross-sectional views of the servo motor from two sides according to this disclosure. The motor 10 includes a housing 11, a stator 12, and a rotating shaft 13. The housing 11 has a first vent hole 111 (also refer to FIG. 2). The stator 12 is positioned in the housing 11. The rotating shaft 13 is installed in the housing 11 and rotates under the electromagnetic action of the stator 12. In this embodiment, the rotating shaft 13 is partially hollow, and at least one second vent hole 130 is defined on the rotating shaft 13. Additionally, the second vent hole 130 communicates with the first vent hole 111, allowing gas to flow through the first vent hole 111 and the second vent hole 130. It should be noted that the stator 12 is simplified, and the winding structure is not shown.

It is worth noticing that the housing 11 is equipped with the first vent hole 111 that may be connected to a vacuum pump. The hollow portion of the rotating shaft 13 and the arrangement of the second vent hole 130 are disposed to form a vacuum flow path in the housing 11. The gas inside the housing 11 flows through the hollow portion of the rotating shaft 13 and be extracted from the first vent hole 111 after passing through the second vent hole 130.

In this embodiment, the housing 11 includes a back cover 12 to seal the encoder 20. The back cover 12 is located on the rear side of the rotating shaft 13 and is combined on the outer side of the encoder 20, and the back cover 12 does not cover the first vent hole 111.

The encoder 20 is disposed in the housing 11 and is configured to detect the rotation information of the motor 10 and encode the rotation information into a signal. Specifically, the encoder 20 is a reflective encoder that includes a sensing element-light source 22, and the sensing element-light source 22 is located on the same side as the encoding disk 23. Furthermore, the encoder 20 is installed on one end of the rotating shaft 13, but this is not a limitation. It should be noted that the encoder 20 may be configured as a transmissive encoder, which may be selected based on actual usage requirements.

It should be noted when the encoder 20 is set as a reflective encoder. The reflective encoder has advantages such as easy assembly and small size. Due to the small size of the reflective encoder, the contact area with the motor body is minimized, which prevents the heat from the motor stator from being transferred to the encoder 20 and allows the heat to be dissipated directly to the outside, thereby improving the heat dissipation effect. Additionally, the encoder the location where the encoder 20 is installed is a closed space with high sealing properties; thus the encoder 20 is protected from being contaminated by external substances, resulting in higher reliability for the encoder 20.

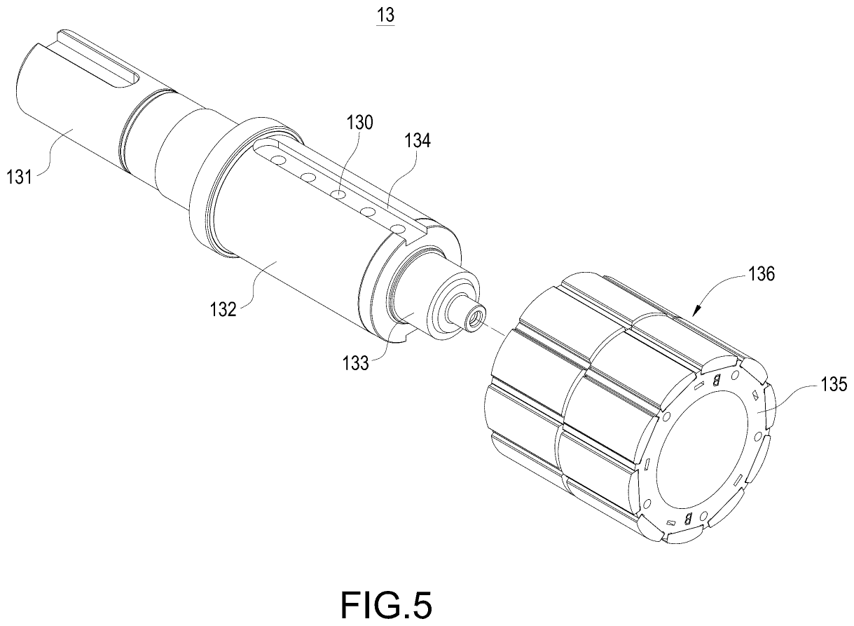

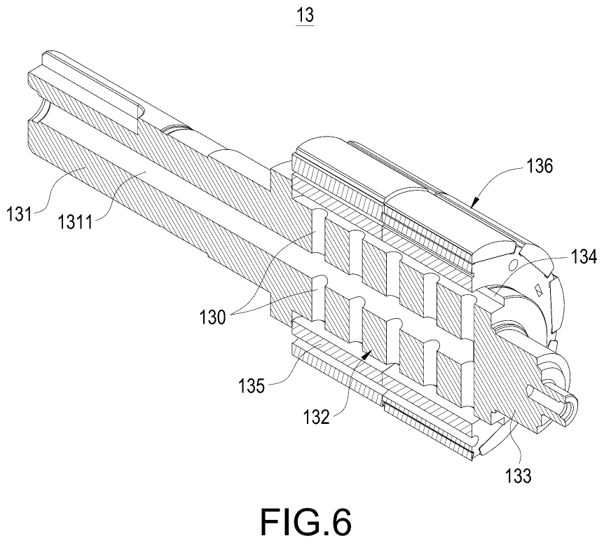

Please refer to FIG. 5 and FIG. 6, which depict a perspective exploded view and a cross-sectional view of the rotating shaft according to this disclosure. Please also refer to FIG. 3 and FIG. 4. The rotating shaft 13 includes a front shaft section 131, a middle shaft section 132 and a rear shaft section 133. The front shaft section 131 has a hollow passage 1311 and is partially hollow, protruding out from the housing 11. The middle shaft section 132 is located corresponding to the stator 12, and the second vent hole 130 is defined on the middle shaft section 132. One end of the second vent hole 130 communicates with the hollow passage 1311. The rear shaft section 133 extends from the middle shaft section 132, and the encoder 20 is combined on the end of the rear shaft section 133.

Specifically, a groove 134 is defined on the middle shaft section 132 of the rotating shaft 13, and the second vent hole 130 is located corresponding to the groove 134. Additionally, the number of second vent holes 130 is multiple. The second vent holes 130 are arranged spacedly in the middle shaft section 132 and respectively communicate to the hollow passage 1311. In this embodiment, the hollow passage 1311 is located at the center of the front shaft section 131 and extends from the front shaft section 131 to the middle shaft section 132. Additionally, the second vent holes 130 are defined on the middle shaft section 132 and are located on two side of the hollow passage 1311 correspondingly.

Moreover, the rotating shaft 13 includes a rotor silicon sheet 135 and a plurality of magnets 136. The rotor silicon sheet 135 surrounds the inner side of the stator 12. The magnets 136 are attached to outside of the rotor silicon sheet 135. The rotor silicon sheet 135 and the magnets 136 are configured as a rotor structure and are positioned at the middle shaft section 132 to generate rotation under the electromagnetic action of the stator 12. Additionally, the rotor silicon sheet 135 is made up of stacked thin silicon steel sheets to shorten the eddy current path and achieve the effect of reducing eddy current losses. However, this is not a limitation in actual implementation.

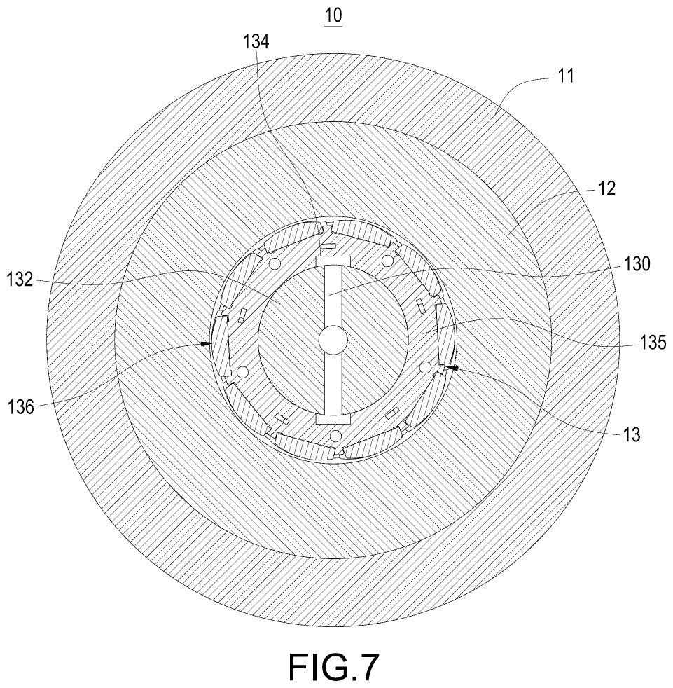

Please further refer to FIG. 7, which depicts another embodiment of the servo motor with a groove defined on the rotating shaft according to this disclosure. In this embodiment, the groove 134 is defined on the rotating shaft 13 of the servo motor 1, and the second vent hole 130 is disposed corresponding to the position of the groove 134. Compared to the groove 134 located at the middle shaft section 132 in FIG. 4, the groove 134 in FIG. 7 is defined on the rotor silicon sheet 135, and the second vent holes 130 extend to the rotor silicon sheet 135 corresponding to the position of the groove 134.

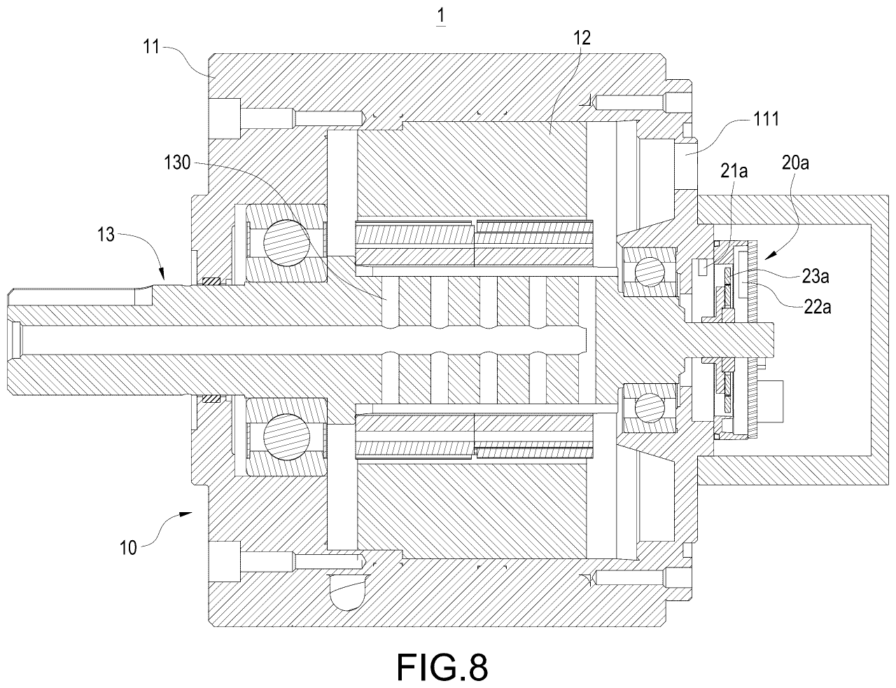

Please refer to FIG. 8, which depicts another embodiment of the encoder of the servo motor according to this disclosure. In this embodiment, the servo motor 1 includes a motor 10 and an encoder 20a. The motor 10 includes a housing 11, a stator 12, and a rotating shaft 13 located in the housing 11. The housing 11 has a first vent hole 111. The rotating shaft 13 is partially hollow, and at least one second vent hole 130 is defined on the rotating shaft 13. The difference in this embodiment compared to FIG. 3 lies in the implementation of the encoder 20a. The encoder 20 in FIG. 3 is a reflective encoder, where the sensing element-light source 22 is located on the same side of the encoding disk 23. In contrast, the encoder 20a in FIG. 8 is a transmissive encoder, with the light source 21a and the sensing element 22a located on different sides of the encoding disk 23a.

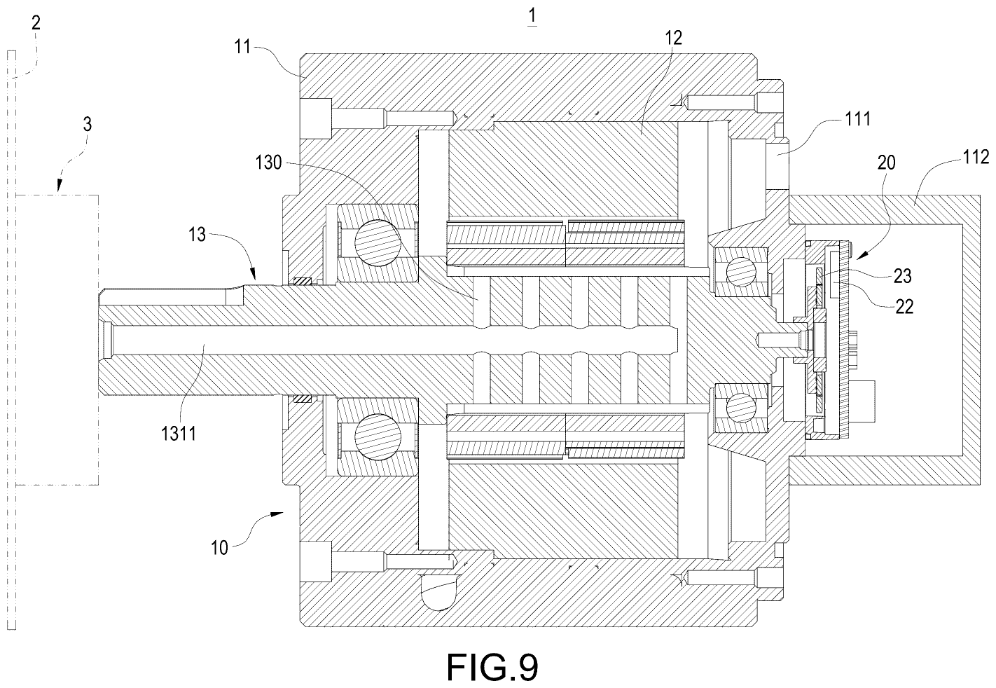

Please further refer to FIG. 9, which is an application schematic view of the servo motor according to this disclosure. The servo motor 1 in this disclosure is used to hold a wafer 2 and drive the wafer 2 to rotate. In some embodiments, the servo motor 1 includes a loading module 3, which is positioned on the rotating shaft 13 that protrudes from the housing 11. Additionally, the loading module 3 includes a suction cup or similar devices, and the interior of the loading module 3 may have a channel design to communicate with the hollow passage 1311 of the rotating shaft 13.

Due to the hollow passage 1311 of the rotating shaft 13 communicating with the second vent hole 130 and the first vent hole 111, when a vacuum device (not shown in the figures) is connected to the first vent hole 111 of the housing 11, the gas inside the housing 11 flows through the hollow passage 1311 (hollow portion) of the rotating shaft 13 and is extracted from the first vent hole 111 after passing through the second vent hole 130. As a result, a negative pressure is formed inside the housing 11, allowing the loading module 3 (such as a suction cup) to generate a suction and fixation effect.

Accordingly, the loading module 3 is fixed to the rotating shaft 13 of the servo motor 1 and is driven by the rotating shaft 13 to rotate on one side of the servo motor 1. Additionally, the loading module 3 may hold the wafer 2. The servo motor 1 may drive the wafer 2 to rotate. It should be noted that through the flow path design of this disclosure, a vacuuming effect is achieved, thereby generating a stable suction force from the inside of the servo motor 1. As a result, the loading module 3 and the wafer 2 are combined through the negative pressure generated therebetween, which ensures that the loading module 3 carried by the servo motor 1 may securely hold the wafer 2, thus preventing failures in the coating process.

It is worth noticing that the gas flow path of the servo motor 1 allows the gas inside the housing 11 to flow through the hollow passage 1311 (hollow portion) of the rotating shaft 13 and be extracted from the first vent hole 111 after passing through the second vent hole 130. Therefore, the gas inside the servo motor 1 in this disclosure does not flow through the encoder 20, ensuring that the encoder 20 is not subjected to air contamination and maintains accuracy.

While this disclosure has been described by means of specific embodiments, numerous modifications and variations may be made thereto by those skilled in the art without departing from the scope and spirit of this disclosure set forth in the claims.

What is claimed is:

1. A servo motor, comprising:
a motor, comprising;
a housing, comprising a first vent hole;
a stator, positioned in the housing; and
a rotating shaft, installed in the housing and configured to rotate by an electromagnetic action of the stator, wherein the rotating shaft is partially hollow, and at least one second vent hole is defined on the rotating shaft for gas to circulate between the first vent hole and the second vent hole; and
an encoder, located in the housing and configured to detect a rotation information of the motor and encode the rotation information into a signal.

2. The servo motor according to claim 1, wherein the housing comprises a back cover sealing the encoder, and the back cover is located on a rear side of the rotating shaft and free from covering the first vent hole.

3. The servo motor according to claim 1, wherein the rotating shaft comprises a front shaft section, a middle shaft section, and a rear shaft section, the front shaft section comprises a hollow passage, the front shaft section is partially hollow and protrudes from the housing, the middle shaft section is located corresponding to the stator, the second vent hole is defined on the middle shaft section, an end of the second vent hole communicates with the hollow passage, the rear shaft section extends from the middle shaft section, and the encoder is combined on an end of the rear shaft section.

4. The servo motor according to claim 3, wherein the hollow passage is located at a center of the front shaft section and extends from the front shaft section to the middle shaft section.

5. The servo motor according to claim 3, wherein a groove is defined on the middle shaft section, and the second vent hole is located corresponding to the groove.

6. The servo motor according to claim 3, wherein a number of the second vent hole is multiple, and a plurality of second vent holes are spacedly defined on the middle shaft section and communicating to the hollow passage.

7. The servo motor according to claim 6, wherein the second vent holes are defined on the middle shaft section and located on two sides of the hollow passage.

8. The servo motor according to claim 1, wherein the rotating shaft comprises a rotor silicon sheet and a plurality of magnets, the rotor silicon sheet surrounds an inner side of the stator, and the magnets are attached to outside of the rotor silicon sheet.

9. The servo motor according to claim 8, wherein a groove is defined on a middle part of the rotating shaft, the groove is located on the rotor silicon sheet, and the second vent hole extends to a position of the rotor silicon sheet corresponding to the groove.

10. A semiconductor equipment for driving a wafer, the semiconductor equipment comprising:
a servo motor, comprising:
a motor, comprising;
a housing, comprising a first vent hole;
a stator, positioned in the housing; and
a rotating shaft, installed in the housing and configured to rotate by an electromagnetic action of the stator, wherein the rotating shaft is partially hollow, and at least one second vent hole is defined on the rotating shaft for gas to circulate between the first vent hole and the second vent hole; and
an encoder, located in the housing and configured to detect a rotation information of the motor and encode the rotation information into a signal; and
a loading module, fixed on the rotating shaft of the servo motor, wherein the loading module is driven by the rotating shaft of the servo motor and rotates on one side of the servo motor, and the wafer is adsorbed by a negative pressure and rotates with the loading module.

11. The semiconductor equipment according to claim 10, wherein the housing comprises a back cover sealing the encoder, and the back cover is located on a rear side of the rotating shaft and free from covering the first vent hole.

12. The semiconductor equipment according to claim 10, wherein the rotating shaft comprises a front shaft section, a middle shaft section, and a rear shaft section, the front shaft section comprises a hollow passage, the front shaft section is partially hollow and protrudes from the housing, middle shaft section is located corresponding to the stator, the second vent hole is defined on the middle shaft section, an end of the second vent hole communicates with the hollow passage, the rear shaft section is extended from the middle shaft section, and an end of the rear shaft section is combined with the encoder.

13. The semiconductor equipment according to claim 12, wherein the hollow passage is located at a center of the front shaft section and extends from the front shaft section to the middle shaft section.

14. The semiconductor equipment according to claim 12, wherein a groove is defined on the middle shaft section, and the second vent hole is located corresponding to the groove.

15. The semiconductor equipment according to claim 12, wherein a number of the second vent hole is multiple, and a plurality of second vent holes are spacedly defined on the middle shaft section and communicating to the hollow passage.

16. The semiconductor equipment according to claim 15, wherein the second vent holes are defined on the middle shaft section and located on two sides of the hollow passage.

17. The semiconductor equipment according to claim 10, wherein the rotating shaft comprises a rotor silicon sheet and a plurality of magnets, the rotor silicon sheet surrounds an inner side of the stator, and the magnets are attached to outside of the rotor silicon sheet.

18. The semiconductor equipment according to claim 17, wherein a groove is defined on a middle part of the rotating shaft, the groove is located on the rotor silicon sheet, and the second vent hole extends to a position of the rotor silicon sheet and is corresponding to the groove.
